(19) United States
(12) Patent Application Publication
(10) Pub. No.: US 2014/0326482 A1
(43) Pub. Date: Nov. 6, 2014

(54) Iridium Oxide Coating with Cauliflower Morphology for Functional Electrical Stimulation Applications

(71) Applicants: Sachin Thanawala, Lancaster, NY (US); Cheng He, Ottawa (CA)

(72) Inventors: Sachin Thanawala, Lancaster, NY (US); Cheng He, Ottawa (CA)

(73) Assignee: Greatbatch Ltd., Clarence, NY (US)

(21) Appl. No.: 13/549,612

(22) Filed: Jul. 16, 2012

Related U.S. Application Data
(60) Provisional application No. 61/508,396, filed on Jul. 15, 2011.

(51) Int. Cl. H01B 5/00; C23C 14/38

(52) U.S. Cl. 174/126.2; 204/192.15

(57) ABSTRACT

An iridium oxide coating for application on an external surface of an electrode of a medical lead is described. The iridium coating is applied using pulse DC sputtering. The coating provides the electrode with an increased double layer capacitance and a reduced electrical impedance. The iridium oxide coating is characterized as having a dense structure with a surface morphology having the general appearance of a fractal or cauliflower shape. The pulse DC sputtered iridium oxide coating is achieved through a mixture ratio of oxygen and argon gases, a sputtering power of between 75 to 125 W, a chamber pressure ranging from about 20-30 mTorr, and a frequency ranging from 50 kHz to 150 kHz. The coated electrode may be used to facilitate the injection of electrical charge stimulation and/or monitor biorhythms of cardiac and neurological tissue.

### CROSS REFERENCE TO RELATED APPLICATIONS

This application claims priority to U.S. provisional application Ser. No. 61/508,396, filed on Jul. 15, 2011.

### BACKGROUND OF THE INVENTION

1. Field of the Invention

This invention relates to coatings for implantable electrodes such as pacing electrodes, neurostimulator electrodes, electroporating electrodes, and sensing electrodes. More particularly, the present invention is directed to the application of iridium oxide on the surfaces of electrodes used to provide therapy in cardiac rhythm management and neuromodulation applications.

2. Prior Art

Active implantable devices typically have at least one medical lead comprising a series of electrodes. The electrodes are typically positioned along the medical lead such that when the medical lead is inserted within the body, the electrode is positioned adjacent to or in physical contact with body tissue. These electrodes, therefore, are designed to facilitate electrical stimulation and/or sensing of electrical bio-rhythms between the medical device and body tissue.

In general, the external surface of the electrode is positioned to be in contact with the intended body tissue. At the same time, an internal electrode surface is electrically connected to the lead and the medical device. Typically, the electrical performance of these electrodes can be enhanced by applying a coating to the external surfaces of the electrodes. These coatings are intended to provide an electrically optimized interface with the tissue of the body with which the electrode is in contact.

In general, it is known that the application of a coating having a high surface area or a highly porous structure, to that of an implantable medical device electrode, increases the double layer capacitance of the electrode and thereby reduces the after-potential polarization. Such properties are beneficial in that they typically increase the battery life of the device and allow for lower capture thresholds for improved sensing of certain electrical signals, such as R and P waves. Furthermore, a high surface area coating generally facilitates a reduction in after-potential polarization. A reduction in after-potential polarization is generally desirable in that it results in an increase in charge transfer efficiency by allowing increased charge transfer at lower voltages. This is of particular interest in providing neurological tissue stimulation.

The double layer capacitance is typically measured by means of electrochemical impedance spectroscopy (EIS). In this method an electrode is submerged in an electrolytic bath and a small (10 mV) cyclic wave form is imposed on the electrode. The current and voltage response of the electrode/electrolyte system is measured to determine the double layer capacitance. The capacitance is the predominant factor in the impedance at low frequencies (<10 Hz) and thus the capacitance is typically measured at frequencies of 0.001 Hz to 1 Hz.

Iridium oxide has been found to be suitable as an electrode coating. The material is known to exhibit excellent biocompatibility properties and is effective in providing charge injection to tissue. Iridium oxide also comprises a double layer capacitance which helps facilitate lower capture thresholds and improved sensing of certain bioelectrical signals, such as R and P waves.

Iridium oxide belongs to a class of materials known as “valence change oxides”. Specifically, iridium oxide comprises a reversible valence change of (Ir⁴⁺/Ir³⁺) that makes it possible to inject an electrical charge. During charge injection, the oxide shuffles between these valence states and, as a result, transfers charge across the electrode-tissue interface using a proton-electron reaction. The proton-electron reaction is generally described by the equation:

Ir(OH)₂ [symbol] IrO(OH)+H⁺+e⁻

Layers of iridium oxide may be formed on the surface of a substrate, such as the surface of an electrode, by various methods including, thermal decomposition of an iridium salt, electrochemical activation of an iridium metal, or by various film deposition techniques. One such film deposition technique is reactive sputtering. Reactive sputtering is the use of a gas to react with the target material within the sputter chamber to elicit a layer of sputtered material on a surface. Reactive sputtering of an iridium target is often used to deposit layers of iridium metal on the electrode surface.

Sputter deposited iridium oxide films have been found to be suitable for electrode fabrication in neural stimulation applications due to their high corrosion resistance and mechanical stability. Compared to other deposition techniques, such as chemical vapor deposition, sputtering offers the advantage of lower processing temperatures, which minimizes the possibility of causing undesirable material reactions. There are generally three distinct sputtering techniques, radio frequency (RF), direct current (DC), and pulsed direct current. Each of these sputtering methods may be used to apply a layer of oxide, such as iridium oxide, on the surface of a substrate.

In addition, the environment within the sputter chamber can affect the quality of the deposited material. For example, an oxygen rich environment typically results in the undesirable oxidation of the target material. Such oxidation of the target, especially in the case of an insulating oxide, may lead to an undesirable charge accumulation at the oxide target surface. Furthermore, reactive sputtering in an oxygen environment can cause micro-arc formation that may result in low quality films. Such low quality oxide films may be deficient in uniform coverage and/or adhesion to the substrate surface.

In the case of conducting oxides, such as iridium oxide (IrO₂), oxidation of the sputter target may result in decreased deposition rates. Metastable, non-stoichiometric iridium oxide phases may form during a reactive sputtering process as well. Such metastable iridium oxide phases typically have considerably lower electrical conductivity than stoichiometric IrO₂, and therefore, micro arching and other undesirable phenomena may affect the film quality. In addition, undesirable micro-particles may form within the film, thereby potentially negatively affecting the adhesion and/or electrical conduction properties of the resulting coating.

Furthermore, non-uniform oxidation of the target material can cause local heating of the target, which may result in uncontrolled ejection or “spitting” of molten material from the target. Such uncontrolled ejection of target material may result in undesirable non-stoichiometric micro-inclusions within the deposited layer of iridium oxide. Such micro-inclusions may adversely affect the electrical properties of the resulting coating such as reducing its charge injection capabilities or increasing the electrical impedance of the coated material.

However, there is still a need for an implantable electrode having the requisite biocompatibility and biostability characteristics, such as provided by a dense layer of iridium oxide material, but that advances the state of the art through high specific surface characteristics. In that light, the result of the present invention is an iridium oxide coated electrode with an improved lower polarization rise upon stimulation than is currently provided. The present electrode fulfills this need in terms of both low polarization and minimum energy requirements for acceptable sensing properties achieved by pulsed DC sputtering of the coating.

Pulsed direct current (DC) sputtering addresses these shortfalls of the prior art. Pulsed DC sputtering utilizes a pulsing power to reactively provide a layer of material on surface of the substrate. The pulsed power of the DC sputtering, therefore, minimizes the undesirable electrical arcing of the sputter target in comparison to other non-pulsed sputtering techniques. In addition, the pulsed DC deposition process provides a controlled reduced oxygen environment. Such a controlled environment reduces the oxidation issues of the prior art.

The foregoing and additional objects, advantages, and characterizing features of the present invention will become increasingly more apparent upon a reading of the following detailed description together with the included drawings.

### SUMMARY OF THE INVENTION

The present invention meets these objectives by disclosing an optimized surface geometry and process of manufacturing thereof for an implantable medical electrode, which optimizes the electrical performance of the electrode while mitigating the undesirable effects of the prior art.

More specifically, an iridium oxide coating is provided with an enhanced double-layer capacitance and charge injection capabilities. The iridium oxide coating of the present invention is designed to be applied to the surface of an electrode of a medical lead such that the coating provides an increase in surface area of the electrode. Such an increase in surface area improves the electrochemical sensitivity of the electrode through a reduction of the electrode's overall electrical impedance.

This improvement in electrochemical sensitivity improves the electrode's ability to sense lower amplitude biopotentials and biorhythms at lower frequencies for cardiac rhythm management and neuromodulation applications.

In addition, the improved pulsed DC sputtering process provides an iridium oxide material with an optimum “cauliflower” surface morphology with increased material density. The improved coating density translates into improved charge injection capabilities, which, thus leads to a reduction of driving voltage required to inject the stimulus, thereby, increasing battery life of the device.

The improved properties of the iridium oxide material are achieved through a pulsed DC sputtering process. The parameters of the sputtering process have been optimized to produce the desired iridium coating of the present invention. The sputtering process utilizes an “on-off” pulsed direct current that activates the sputter target material such that the material leaves the target surface and is deposited on the surface of a substrate located within the chamber of the sputter instrument. The “on-off” pulsation of the direct current reduces the likelihood of charge accumulation at the oxide sputter target surface. Such charge accumulation, at the surface of the oxide target, typically results in undesirable micro charge arcing and a reduction of deposition rates. On the other hand, the pulsed DC sputtering process of the present invention utilizes a pulse DC sputtering method comprising an increased sputter chamber vacuum pressure and a controlled argon/oxygen gas mixture. These parameters, as will be further explained, minimize micro sputter target charge arching thereby enhancing the double-layer capacitance and charge injection capabilities of the iridium oxide material.

### BRIEF DESCRIPTION OF THE DRAWINGS

FIG. 1 illustrates an embodiment of an electrode of a medical device lead, a portion of which is coated with a layer of iridium oxide of the present invention.

FIG. 1A shows a magnified cross-sectional view of the coated portion of the electrode shown in FIG. 1.

FIG. 2 illustrates an alternate embodiment of an electrode on which a layer of iridium oxide of the present invention may be applied.

FIG. 2A illustrates an additional embodiment of an electrode on which a layer of iridium oxide of the present invention may be applied.

FIG. 3 illustrates an embodiment of a “Utah” type electrode array assembly on which a layer of iridium oxide of the present invention may be applied.

FIG. 3A shows an embodiment of a “Michigan” type electrode array assembly on which a layer of iridium oxide of the present invention may be applied.

FIG. 4 is a scanning electron micrograph image of the surface of an embodiment of the iridium oxide material of the present invention, magnified at 50 k times, on a substrate surface.

FIG. 4A is a scanning electron micrograph image of the surface of the embodiment of the iridium oxide material shown in FIG. 4 magnified at 50 k times.

FIG. 5 is an illustration of various x-ray diffraction patterns of iridium oxide that has been applied through a radio frequency (RF) sputtering technique.

FIG. 5A is an illustration of various x-ray diffraction patterns of iridium oxide that has been applied through pulsed DC sputtering process of the present invention.

FIG. 6 shows the results of various electrochemical impedance spectroscopy (EIS) measurements of both iridium oxide coated and non-coated surfaces,

### DETAILED DESCRIPTION OF THE PREFERRED EMBODIMENT

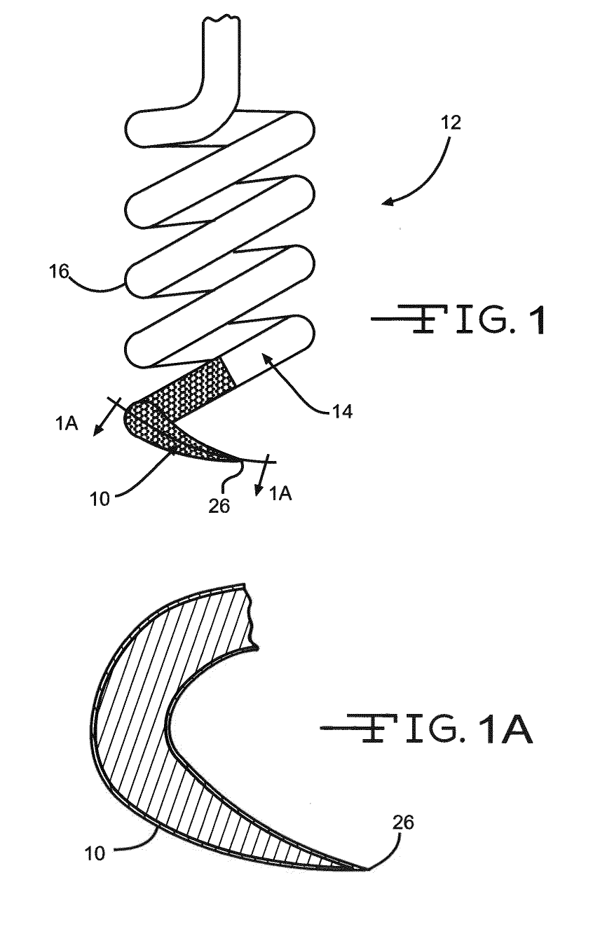

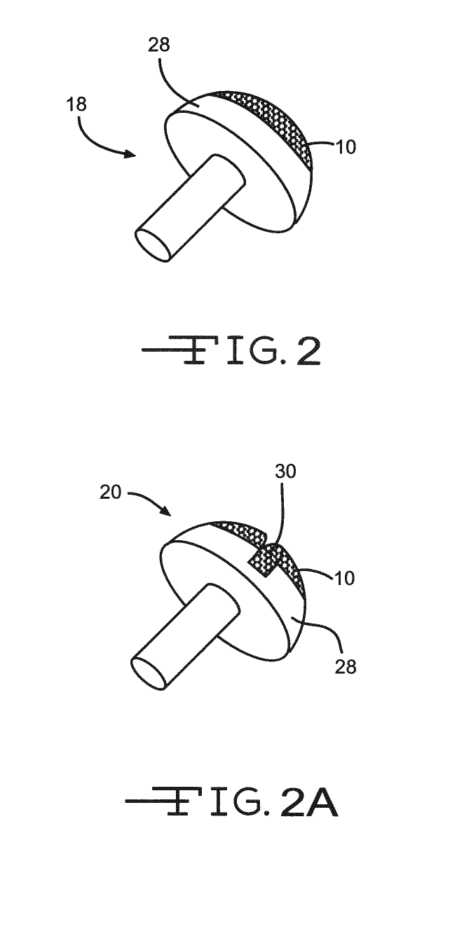

Now referring to the figures, FIGS. 1 and 1A illustrate an embodiment of a coating 10, of the present invention, designed to be applied to a substrate 12, specifically an electrode of a medical lead (not shown) for use in cardiac or neuromodulation applications. Specifically, the coating 10 is to be applied to at least a portion of an external surface 14 of the substrate 12, i.e., an electrode. The medical lead, in turn, is designed to be connectable to a cardiac rhythm management device or neuromodulation device such as a pacemaker, defibrillator, neurostimulator or the like. In addition, methods of manufacture, in accordance with the present invention, are also provided.

In an embodiment, of the present invention, the coating or film 10 of the iridium oxide material is applied to the external surface 14 of the medical electrode 12 through the use of a sputtering technique. More preferably, the coating or film 10 of the iridium oxide material can be applied through pulsed direct current (DC) reactive sputtering. Such film formation conditions can form a polycrystalline iridium oxide film 10 adhering to the exterior surface 14 of the medical electrode 12.

Pulsed DC reactive sputtering is a method of growing or forming a layer of material on a suitable substrate such as a metallic, ceramic, or semi-metal substrate. To effectively form a sputtered layer, a reactive gas, such as oxygen, is introduced into the reaction sputter chamber during sputtering of a source material target, e.g., an iridium plate. The reaction between the reactive gas and sputtered atoms, at the surface of the electrode, forms a reacted species layer, in this case, iridium oxide. Deposition conditions and parameters can be altered and optimized to form layers 10 of iridium oxide with varying properties, as desired.

Electrodes 12 for use in biological matter can be configured to withstand the harsh biological environments, while still maintaining desired functionality. In order to protect the stability of the electrode 12, the exterior surface or surfaces 14 of the electrode or electrodes 12 can be covered with a film 10 formulated to provide the desired protection and long-term stability. Unfortunately, many films that may be used to protect the electrode in the biological environment drastically reduce the functionality of the electrode 12. In certain embodiments, therefore, the film 10 can be formed on the exterior surface 14 of the electrode 12 that does not significantly reduce the effectiveness of the electrode, such is the case with the DC pulsed reactive sputtered iridium oxide films 10 presented herein. Iridium oxide films 10 deposited through DC pulsed reactive sputtering provide significant advantages compared to other means of producing iridium oxide films as described further below.

The electrodes 12 of the present invention can be any configuration and size which are suitable for recording and/or stimulating cardiac or neurological tissue. Such electrodes 12 can be of a variety of geometries, including two-dimensional and three-dimensional electrodes designed to be in contact with myocardial or neurological tissue. In a specific embodiment, the electrode 12 can be an array of individually controllable electrodes 12.

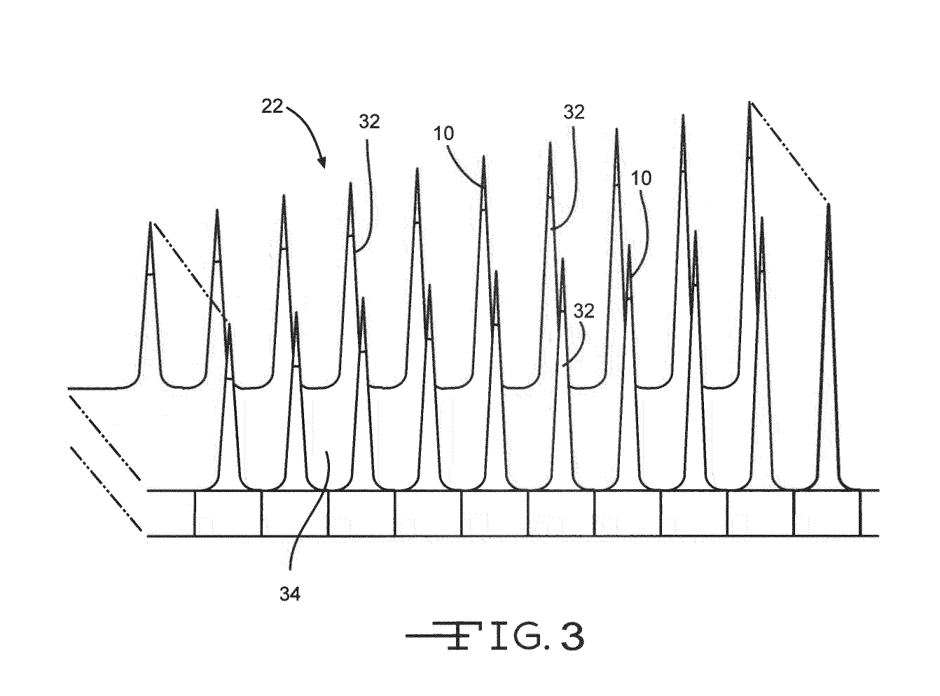

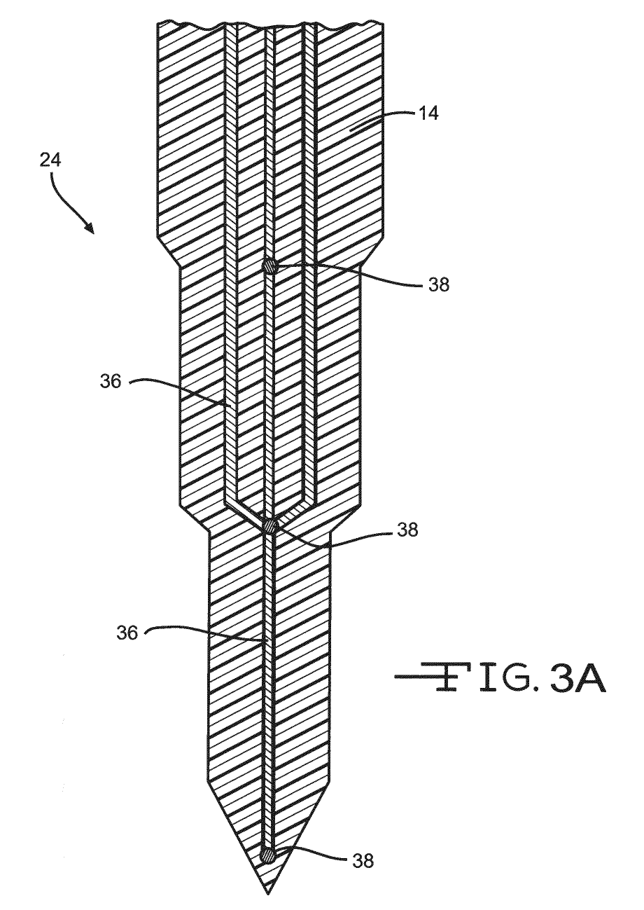

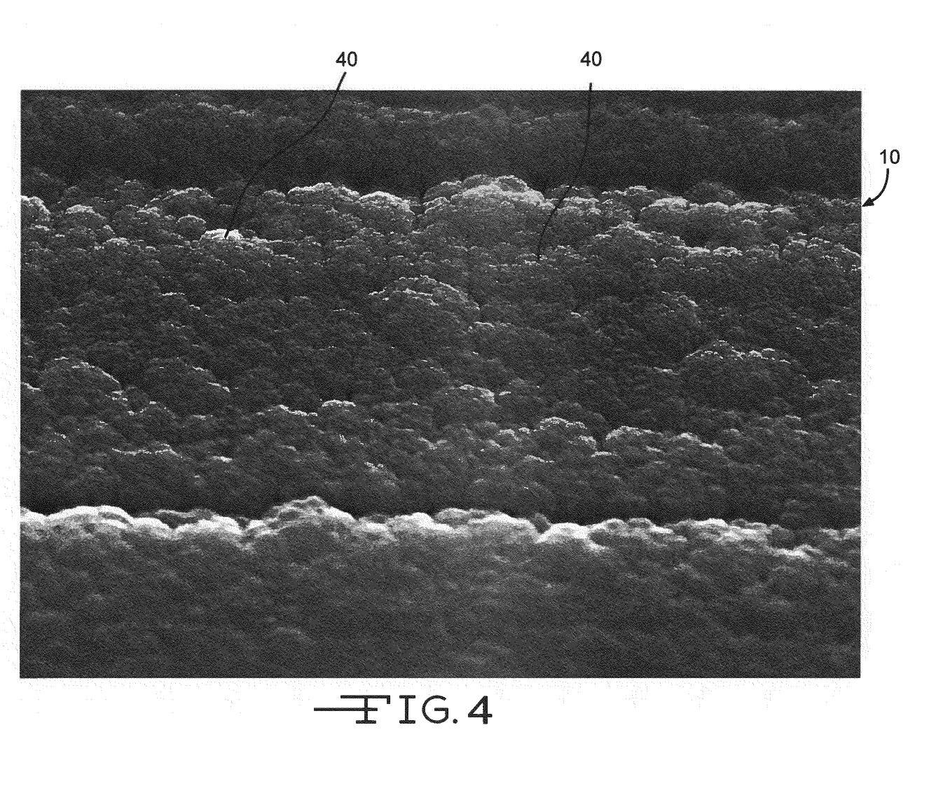

Non-limiting examples of suitable electrodes 12 may embody a helically shaped electrode 16, as shown in FIG. 1, or various domed shaped electrodes 18, 20 as shown respectively in FIGS. 2 and 2A. In addition, the layer 10 of iridium oxide may be applied to an external surface of an electrode array, such as a “Utah” Electrode Array (UEA) 22, embodied in FIG. 3, and a “Michigan” Electrode Array (MEA) 24, embodied in FIG. 3A. Such electrode array embodiments are generally useful for neurological tissue stimulation.

As shown, the helically shaped electrode 16 comprises a tip 26 that is designed to be positioned within body tissue, particularly that of myocardiac tissue. As shown in FIG. 1, the layer 10 of iridium oxide is supported on a portion of the external surface 14 of the electrode 12, specifically the helically shaped electrode 16. When positioned within tissue, the coated surface forms an intimate contact with the targeted tissue. The domed electrode 18 embodied in FIG. 2 is designed to be positioned adjacent to, or in physical contact with, the external surface of the body tissue. As shown, a domed top surface 28 is coated with a layer 10 of iridium oxide of the present invention. Once coated, the domed top surface 28 is positioned adjacent the body tissue. Alternatively, the embodiment of the dome shaped electrode 20 shown in FIG. 2A, may comprise a slot 30. The slot 30 may provide additional surface area that is in contact with tissue.

Furthermore, the electrodes 12 can be configured in a non planar or planar configuration. Specifically, the UEA 22 is a non-planar configuration where the electrodes are formed three-dimensionally from a starting material. As shown in FIG. 3, the UEA 22 comprises a series of pins 32 that extend from a base 36 of the array 22. Preferably, the iridium oxide of the present invention is applied such that at least a portion of the exterior surface of the pins 32 of the array 22 is coated with the layer 10 of iridium oxide.

In contrast, a planar electrode is an electrode 12 which is typically formed in a plane of a starting material and then etched out and arranged into a usable array or other configuration. Planar electrodes, like the Michigan electrode array 24, embodied in FIG. 3A, may have more than one active surface. As shown, the MEA 24 comprises an electrically conductive trace 36 and a node 38 at which some of the traces 36 meet. Planar electrodes, such as the Michigan electrode array 24, can be positioned within the tissue or alternatively positioned such that they are in contact with the surface of the tissue. The sputtered layer 10 of iridium oxide of the present invention may be applied to the surface of these planar electrodes. Specifically, the layer 10 of iridium oxide may be deposited on a portion of the conductive trace 36 and/or node 38. Additionally a layer of conductive material may be applied to the surface of the planar electrode to facilitate adhesion of the layer 10 of the iridium oxide of the present invention.

The medical electrodes 12, on which the coating 10 of iridium oxide is applied, may be formed of a suitable base material. The base material may comprise an electrically conductive or an electrically insulative material. In the case of an insulative base material, an electrically conductive coating or other feature providing an electrically conductive pathway, is preferably positioned on the surface of the electrode 12. Non-limiting examples of suitable electrode base materials may include electrically conductive materials such as iridium, platinum, palladium, platinum iridium alloys, palladium iridium alloys, titanium, titanium tungsten, gold alloys, conductive polymers, and the like. Suitable electrically insulative materials electrode base materials may include such as silicon, and biocompatible polymers. In an embodiment, the electrical insulative base materials may be coated with a conductive layer to provide an electrically conductive path.

Prior to film formation, the exterior surface 14 of the electrode 12 can be pre-treated and/or cleaned. Such pretreatments can include any method that removes debris, native oxide, or other undesired material from the surface sufficient to provide ohmic contact with the sputtered iridium oxide film. Suitable pretreatments can include, but are not limited to, buffered oxide etch (BOE), ultrasonic cleaning, back sputtering or etching, such as plasma etching, and the like.

In one embodiment, the surface 14 of the electrode 12 can be subjected to pulsed DC sputtering at about 50 kW to about 300 kW for about 1 to 20 minutes at a pressure ranging from about 5 mTorr to about 100 mTorr, in an atmosphere comprising a mixture of reactive and inert gases, such as oxygen and argon. In a particular embodiment, the deposition conditions and the electrode can be selected for the film 10 to readily adhere directly to the surface 14 of the electrode 12.

Once the surface of the electrode is properly prepared, pulsed DC sputtering can be used to form the film 10. A sputtering instrument having a pulsed DC generator and at least one inlet gas line for injection of reactive gases which is operatively connected thereto can be used. Typically, the sputtering target can be a substantially pure material, such as an iridium target, although other iridium targets could also be used. In one specific embodiment, the iridium target can be a 3 inch diameter, 0.125 inch thick iridium (99.99% pure) sputtering target, although other diameter and thickness sizes can also be suitable.

Various sputtering parameters can be altered to vary the properties of the deposited layer 10. Non-limiting examples of variable parameters may include sputtering power, sputtering pressure, gas flow, gas mixing ratio, pulsing frequency, reverse bias amplitude and duration, duty cycle percentage, target temperature, chamber temperature, and the like. Sputtering pressure and sputtering power can significantly affect thin film stress, which stress can be compressive or tensile. Low stress and a clean surface of the electrode 12 increases film adherence. Typically, lower pressures make the film relatively more compressive while relatively higher pressures make the film more tensile.

As a general guideline, pulses having a sputtering power from about 5 W to about 500 W can be used, and in some cases, pulses having a sputtering power from about 25 W to about 250 W can also be used. In one specific embodiment, the pulsed DC can have a sputtering power of about 100 W. As a further non-limiting example, the pulse frequency can range from about 5 kHz to about 200 kHz, and in some cases, range from about 25 kHz to 150 kHz. The reactive sputtering temperature and pressure can be altered according to the desired film, and in relation to other parameters. In one embodiment, the reactive parameters may include a sputtering pressure from about 4 mTorr to about 80 mTorr, and in some cases, range from about 30 mTorr to about 50 mTorr.

Various reactive conditions can dictate at least some of the physical properties of the resulting film. One condition, in particular, is the gas mixture ratio. The reactive gas mixture ratio is defined by the following mathematical equation, (flow rate of gas “A”)/(flow rate of gas “A”+flow rate of gas “B”) wherein gas “A” may comprise oxygen, argon, nitrogen, helium, neon, a combination thereof, or the like and gas “B” may comprise oxygen, argon, nitrogen, helium, neon, a combination thereof, or the like, wherein gasses “A” and “B” are different. The reactive gas mixture ratio is designed such that the ratio of the different gases holds true for different gas flow rates. For example, to establish a reactive gas mixture ratio of 10 percent, the flow rates for gases “A” and “B” may be set at 10 m³/s and 90 m³/s, respectively, or the flow rates may be set at and 450 m³/s, respectively.

The reactive gas or mixture of gases generally impacts the sputter target, i.e. the iridium target, to cause atoms to be removed. These iridium molecules or atoms travel toward the surface 14 of the desired substrate 12, i.e., the exterior surface 14 of the electrode 12, and are deposited on the surface of the substrate (e.g. at a tip of an electrode 12). While traveling, iridium atoms generally react with the gas or gases, within the sputter chamber. For example, iridium atoms may react with oxygen to form iridium oxide, which eventually are deposited on the surface 14 of electrode 12. A decrease in oxygen flow typically favors deposition of pure iridium metal on the substrate which is not desirable. Increasing the amount of oxygen can reduce pure metal deposition. Inert gases which can be included in the reaction chamber alone or in combination can include, but are not limited to, argon, nitrogen, and the like. Therefore, it is optimal to utilize a reactive gas comprising a mixture of oxygen and an inert gas, such as argon.

In a preferred embodiment, gas “A” comprises oxygen and gas “B” comprises argon. The reactive gas mixture ratio may range from about 1 percent to about 50 percent. More preferably, the reactive gas mixture ratio ranges from about 2 percent to about 10 percent. Most preferably, the reactive gas mixture comprises a mixture of oxygen and argon gases in a reactive gas mixing ratio of between about 1 percent to about 5 percent. This preferred reactive gas mixing ratio encourages production of a dense layer of iridium oxide.

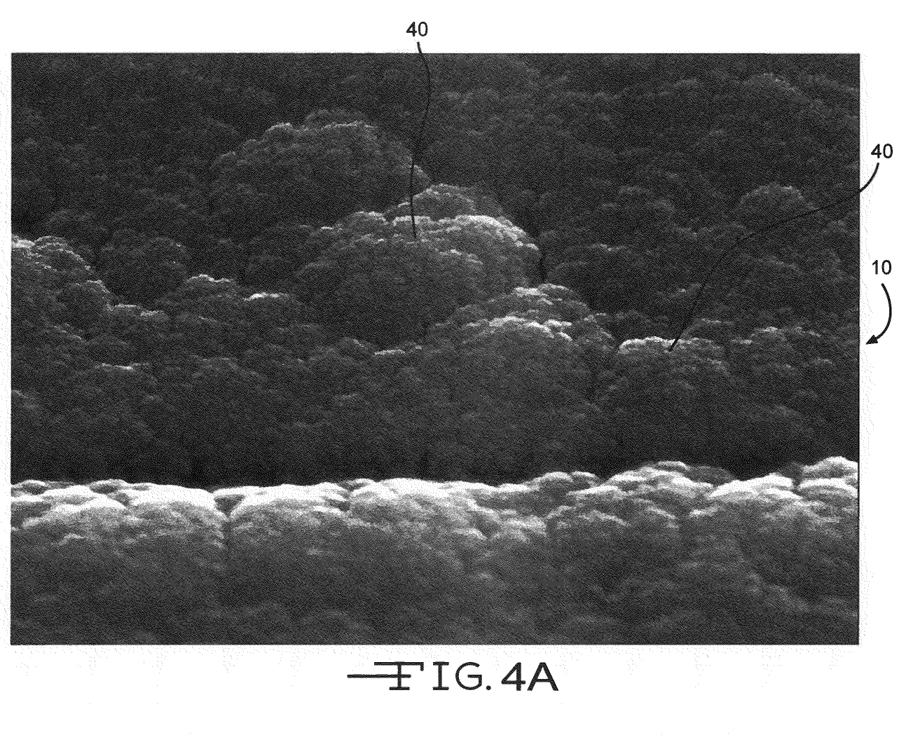

As shown in FIGS. 4 and 4A, this optimal gas mixing ratio encourages production of a layer 10 of iridium oxide having a fractal or “cauliflower” morphology. Morphology is herein defined as the general appearance of the topography of the coated surface.

More specifically, the morphology of the iridium oxide coating 10 typically resembles a self-similar, densely packed, repeating topology that displays fractal-like patterns in its growth. The term “fractal” refers to a geometric shape that can be subdivided at any scale into parts that are, at least approximately, reduced-size copies of the whole. The fractal patterned shapes resemble small billowy, bulbous formations that appear to take cluster-like shapes with bulges that appear to have sets of spirals that seem to be going in opposite directions. When viewed via scanning electron microscopy (FIGS. 4 and 4A), the coating forms a structure that closely resembles globe-like or cauliflower-like florets. In other words, the exterior surface of the coating 10 of iridium oxide comprises a plurality of nodules 42 that are densely packed together. These nodules 42 are random in size and surface area and are densely packed together such that the top surface of the nodules 42 are at relatively randomly different heights to each other. The preferred “cauliflower” morphology of the coating 10 of iridium oxide provides an increased surface area with the desired conductive electrical properties.

As with other parameters, the deposition rate and deposition time can affect the resulting film. Such conditions depend on the materials used, and the surface of electrode 12. In one aspect, the film 10 can be deposited at a deposition rate ranging from about 5 nm/min to about 100 nm/min. Deposition can continue until the film 10 is of the desirable thickness. In one aspect, the sputtering can be substantially complete in less than about 60 minutes. The resulting film 10 may be continuous or semi-continuous over individual electrodes. The desirable film thickness can vary depending on the electrode 12 and the anticipated environment for use. The thickness of the deposited layer 10 can also be adjusted based on sputtering time and other conditions. As a general guideline, the film 10 can have an average thickness of about 50 nm to about 1000 nm, although films having a thickness from about 300 nm to about 600 nm are particularly useful. In one specific embodiment, a good iridium oxide film was formed using a sputtering pressure of 25 mTorr, 100 Watt power, 100 kHz frequency, a gas mixture ratio of about 2.5 percent (gas “A” is oxygen and gas “B” is argon) and a deposition time of about 20 minutes to achieve a film thickness of about 500 nm.

Another pulsed DC sputter parameter is the duty cycle percentage. While in operation, the power supply of the sputter instrument is cyclically turned on and off. This cycle of on and off power is referred to as the sputter duty cycle. Specifically, the duty cycle percentage is defined as the ratio between the duration of time that the power supply is turned on to the total time the power supply is turned on and turned off during a sputter deposition cycle. In other words, the duty cycle percentage is defined mathematically by the equation, τₒₙ/(τₒₙ+τ_{off}) where τₒₙ is the amount of time the power supply is turned on and τ_{off} is the amount of time the power supply of the sputter machine is turned off during a sputter run. Preferably, the duty cycle percentage can range from about 5 percent to about 50 percent. More preferably, the duty cycle percentage may range from about 10 percent to about 30 percent and most preferably, the duty cycle percentage can range from about 15 percent to about 25 percent.

In addition to the duty cycle percentage, reverse bias is also an important pulsed DC sputtering parameter. The reverse bias creates a reversal of the charge across the insulating material, thereby reducing undesirable charge accumulation across the surface of the sputter target. The duration of the application of the reverse bias should be controlled. In a preferred embodiment, the duration of the reverse bias may range from about 1 μsec to about 10 μsec. More preferably, the duration of the reverse bias ranges from about 2 μsec to about 4 μsec.

After the film 10 is formed, it can be optionally annealed. Annealing temperatures can also play an important role in film adherence to the external surface 14 of the electrode 12. The annealing temperature can vary depending on the composition of the electrode and the film. In one embodiment, the film 10 can be annealed at a temperature ranging from about 100° C. to about 1000° C. The deposited film 10 may be annealed within an inert atmosphere such as argon or nitrogen, or the film 10 may be annealed in an oxygen or hydrogen comprising atmosphere.

The films 10 created according to the methods described herein can effectively be applied to the exterior surface 14 of the electrode 12 (FIGS. 1, 1A, 2, 2A and 3) to provide stability in a harsh environment such as in a biological system. Furthermore, the particular coating methods utilized herein can form a film having superior performance properties over other stability-imparting films, either of different composition, or similar iridium-based composition formed by a different deposition method. Such properties include low impedance, thus allowing the electrode 12 to function in a manner superior to similar electrodes having different coatings. In one aspect, the impedance of the film 10 can be less than about 10 kΩ. In a further aspect, the average impedance of the film 10 can be less than about 1 kΩ. For comparison, experimental results of RF sputtered iridium oxide films, of a similar composition, but different deposition technique have an average impedance of about 20 KΩ.

The iridium oxide film 10 of the present invention can have an average cathodal charge storage capacity of about 10 mC/cm² to about 20 mF/cm². In comparison, a conventional RF sputtered film has an average charge capacity of about 8 to 10 mC/cm². The electrode 12 can, in one embodiment, have a storage capacity of at least three times an RF sputtered film having a similiar thickness. A greater charge capacity is a very desirable feature for electrodes and results in superior functionality of the electrode 12. In addition, the pulse-DC sputtered iridium oxide coatings have an increased charge injection capacity compared to RF sputtered coatings. In particular, charge injection capacity, i.e. Coulombs (C), is the integral of stimulus current over time divided by active surface area (mC/cm²), i.e. charge injection capacity is (stimulus current X time)/surface area. In some embodiments, depending on thickness, the charge injection capacity can range from about 0.1 to about 10 mC/cm², and in some cases from 4 to about 10 mC/cm². As a general guideline, it has been recognized that the charge storage capacity increases with film thickness while charge injection capacity decreases.

Safe electrical stimulation of the nervous system also generally requires reversible charge injection processes. Typically, this can be the result of utilizing double-layer capacitance and reversible faradaic processes which are confined to the electrode surface. Charge injection by any other faradaic reactions will be at least partially irreversible because products will tend to escape from the electrode surface. Irreversible faradaic reactions include water electrolysis, saline oxidation, metal dissolution and oxidation of organic molecules. However, in iridium oxide the faradaic reactions are confined within the oxide film and hence there are substantially no redox products to diffuse away from the electrode surface. Furthermore, the electrodes can include a protective coating such as parylene or other material which can be coated over the electrode 12 while leaving the tip or active surface exposed. This can help to improve selectivity of the electrode to stimulation of fewer neurons, and in some cases one neuron. Thus, the pulse-DC sputtered material of the present invention allows for use of the electrodes under reversible charge injection conditions.

### EXAMPLES

Table 1 below details the parameters utilized in various trial runs of pulsed DC sputtering depositions of iridium oxide material. Sputtering power, sputtering pressure and oxygen/argon gas mixing ratio were kept constant at 75 W, 8 mTorr and 24 percent, respectively

TABLE 1

| | Pulsing | Reverse Bias | |
|---|---|---|---|
| | Frequency | Duration | Duty Cycle |
| Run Number | (kHz) | (μsec) | Percentage |
| 1 | 25 | 4 | 10 |
| 2 | 25 | 8 | 20 |
| 3 | 25 | 2 | 5 |
| 4 | 50 | 2 | 10 |
| 5 | 50 | 4 | 20 |
| 6 | 75 | 3 | 22.5 |
| 7 | 100 | 1 | 10 |
| 8 | 100 | 2 | 20 |

In comparison, a series of trial runs utilizing RF sputtering, a different sputtering technique, were used to deposit layers of iridium oxide on a surface of an electrode. In RF sputtering, the polarity of the anode-cathode bias is varied at a high rate. In comparison, in DC sputtering, polarity of the anode-cathode bias is kept constant. Table 2 below details the parameters utilized in various RF sputtering trial deposition runs of iridium oxide material.

TABLE 2

| | | RF | Ar | O₂ | Gas |
|---|---|---|---|---|---|
| Run | Pressure | Power | Flow Rate | Flow Rate | Mixing Ratio % |
| Number | (mTorr) | (W) | (sccm) | (sccm) | (O₂/O₂ + Ar) |
| 1 | 8 | 75 | 10 | 8 | 24 |
| 2 | 8 | 75 | 20 | 4 | 14 |
| 3 | 8 | 75 | 5 | 3 | 10 |
| 4 | 8 | 75 | 10 | 4 | 5 |
| 5 | 8 | 75 | 20 | 4 | 3 |
| 6 | 8 | 75 | 22.5 | 3 | 2 |

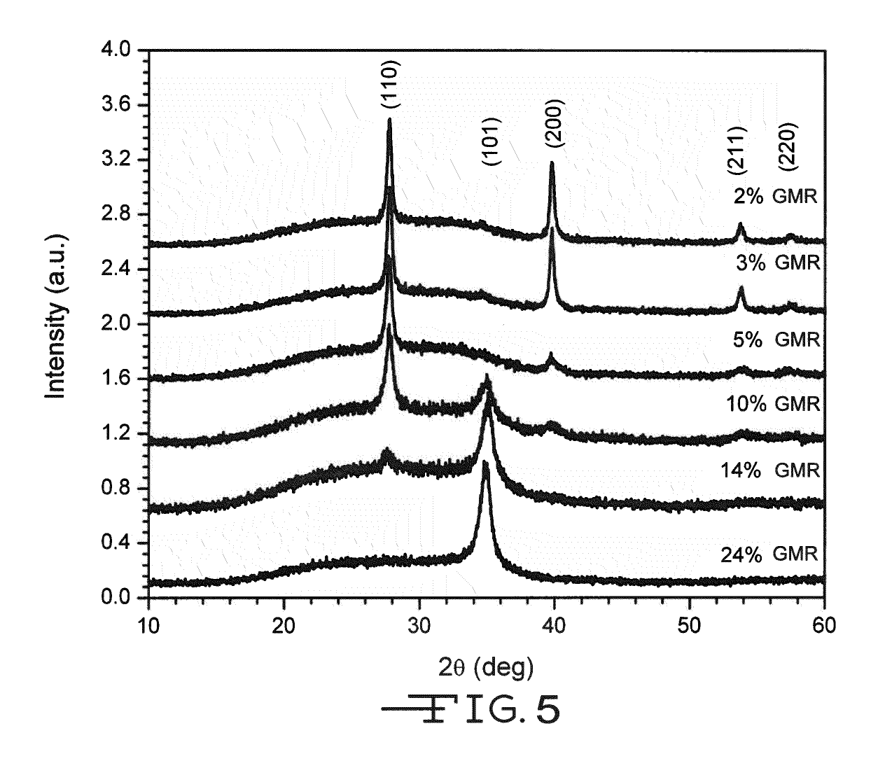

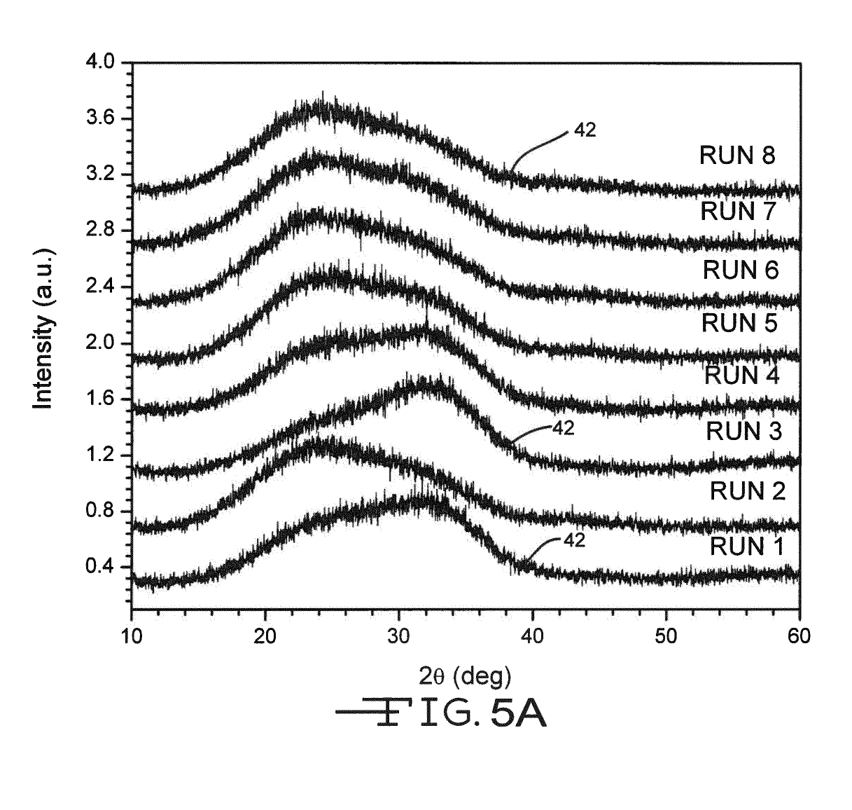

FIG. 5 illustrates an x-ray diffraction (XRD) pattern of the six RF sputtering trial runs detailed in table 2 above. As shown in the XRD pattern, the resulting iridium oxide layers have a generally micro-crystalline structure. This micro-crystalline structure is determined through the defined peaks of the pattern. For example, at a gas mixing ratio of 2 and 3 percent, the iridium oxide film shows defined peaks at about 27′, about 40°, and about 53° 2θ. As shown in the figure, as the gas mixing ratio increases to about 14 and 24 percent, the 27′, 40°, and 53° 2θ peaks disappear and a peak at about 35° 2θ emerges. Nevertheless, the XRD patterns of the RF sputtered iridium oxide samples, show some level of micro-crystalline structure, regardless of the RF sputter parameters chosen.

FIG. 5A illustrates the XRD patterns of the pulsed DC sputtered iridium oxide coating samples formed utilizing the sputter parameters detailed in Table 1. The run numbers identified in FIG. 5A correspond to the run numbers of the sputtering parameters detailed in Table 1.

In contrast, the XRD patterns shown in FIG. 5A do not show any such micro-crystalline structure. As shown, the XRD patterns of the pulsed DC sputtered iridium oxide coatings (FIG. 5A) do not show any defined peaks. Specifically, the elongated rises 42 of the XRD patterns of the pulsed DC sputtered iridium oxide are characteristic of an amorphous solid. Amorphous solids, unlike crystalline solids, do not have a defined crystalline structure as shown by the lack of distinct XRD 20 peaks.

The microstructure of iridium oxide films is important to functionality of electrical stimulation of biological tissue. Electrical stimulation of biological tissue is dictated by the transfer of charge by ions back and forth between the electrode and the physiological media. Hence, for an efficient means of injection of charge within biological tissue, the electrode coating generally processes a relatively high ionic conductivity. Amorphous coatings, such as the iridium oxide coatings of the present invention, have shown to be generally good conductors of ionic species as they possess good electrochromic and electrocatalytic properties. On the other hand, crystalline films such as the iridium oxide films produced through RF sputtering are relatively poorer ion conductors and possess relatively poor electrochromic and electrocatalytic properties.

### Example II

Electrochemical impedance spectroscopy was used to characterize the iridium oxide film surfaces. Layers of iridium oxide were reactively sputtered onto platinum iridium 90/10 electrodes. A standard three electrode glass cell with silver-silver chloride (SSE) reference electrode (Bioanalytical Systems part number MF2078) and a platinum foil was used as the counter electrode for all measurements. All EIS measurements were performed in physiological saline solution (unbuffered aqueous 0.9% NaCl) and phosphate buffered saline (PBS) solution. The EIS measurements were carried out at room temperature with the geometric surface area of the test samples being 0.043 cm² in a Gamry potentiostat system (model PCI4). The AC impedance spectra was measured in the frequency range of 0.01 Hz to 100 kHz using sinusoidal perturbation of 10 mV rms and the EIS data was analyzed using Gamry Echem Analyst software.

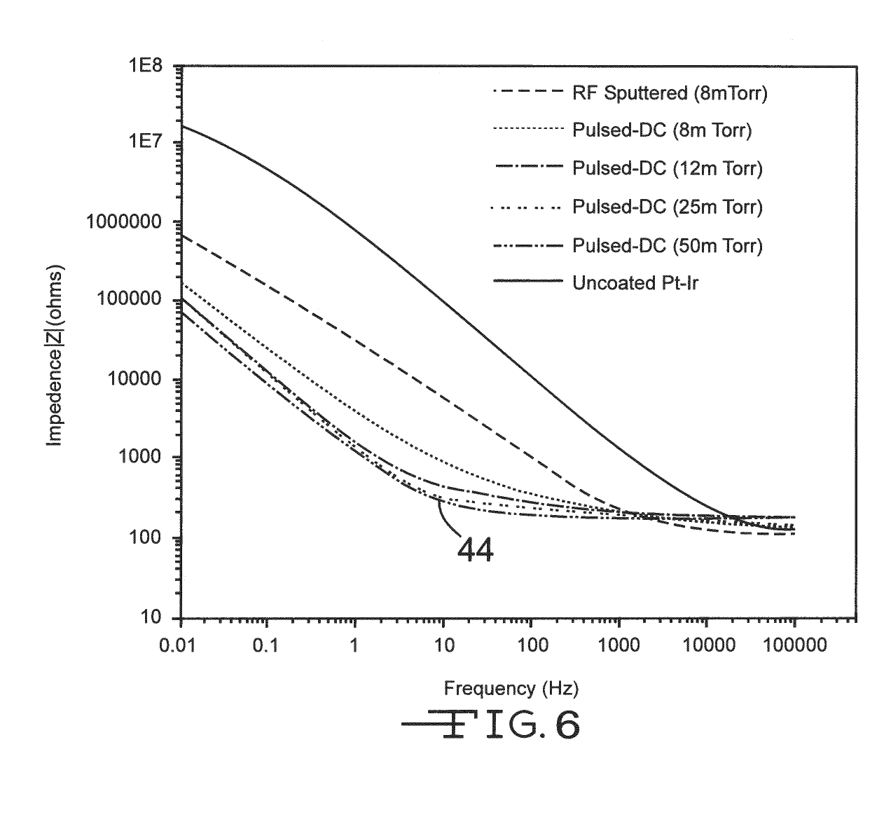

FIG. 6 shows the results of various electrochemical impedance spectroscopy (EIS) measurements of both iridium oxide coated and non-coated electrode surfaces. An uncoated bare electrode was utilized as a test control sample. Specifically, various electrochemical impedance spectroscopy (EIS) measurements of iridium oxide coatings generated with pulsed DC parameters at various sputter pressures ranging from 8 mTorr to 50 mTorr, were compared to the EIS measurement of an iridium oxide coating generated from RF sputtering at 8 mTorr.

As shown by the figure, the iridium oxide coatings generated by pulsed DC sputtering exhibits an overall lower impedance from about 0.01 Hz to about 1,000 Hz as compared to the RF sputtered iridium oxide sample. As can be seem in the figure, the iridium oxide coating generated by pulsed DC sputtering at 50 mTorr exhibits an inflection point 44 that is lower compared to the other iridium oxide RF sputtered coatings. The inflection point 44 occurs at about 7 Hz to 10 Hz along the x-axis of the graph and about 200 ohms to about 225 ohms along the y-axis of the graph. In comparison to the uncoated bare electrode, the iridium oxide coating generated from pulsed DC sputtering having a 50 mTorr pressure, the pulsed DC sputtered iridium oxide coating has a lower impendence range from about 0.01 Hz to about 10,000 Hz.

While this invention has been described in conjunction with preferred embodiments thereof, it is evident that many alternatives, modifications, and variations will be apparent to those skilled in the art. Accordingly, it is intended to embrace all such alternatives, modifications and variations that fall within the broad scope of the appended claims.

1. An electrode, comprising:
a) a substrate having a surface adaptable to interface with biological tissue;
b) a layer of iridium oxide supported on at least a portion of the surface of the substrate; and
c) wherein the layer of iridium oxide is characterized as having been deposited on the surface of the substrate by a pulse DC sputtering technique.

2. The electrode of claim 1 wherein the layer of iridium oxide is characterized as having been formed with a sputter pressure ranging from about 25 mTorr to about 50 mTorr.

3. The electrode of claim 1 wherein the layer of iridium oxide is characterized as having been formed when the surface of the substrate is exposed to a reactive gas selected from the group consisting of oxygen, argon, nitrogen, helium, neon, and combinations thereof.

4. The electrode of claim 1 wherein the layer of iridium oxide is characterized as having been formed when the surface of the substrate is exposed to a mixture of gases having a gas mixture ratio, the gas mixing ratio defined by the equation: (flow rate of gas “A”)/(flow rate of gas “A”+flow rate of gas “B”), wherein gas “A” or gas “B” comprises oxygen, argon, nitrogen, helium, neon, and combinations thereof and wherein gases “A” and “B” are different.

5. The electrode of claim 4 wherein the gas mixing ratio ranges from about 1 percent to about 50 percent.

6. The electrode of claim 4 wherein the gas mixing ratio ranges from about 1 percent to about 25 percent.

7. The electrode of claim 4 wherein the gas mixing ratio ranges from about 1 percent to about 5 percent.

8. The electrode of claim 1 wherein the layer of iridium oxide is characterized as having been formed with a pulse sputter power ranging from about 25 Watts to about 150 Watts.

9. The electrode of claim 1 wherein the layer of iridium oxide comprises a fractal cauliflower-like morphology with an amorphous structure.

10. The electrode of claim 1 wherein the layer of iridium oxide exhibits an electrochemical impedance spectroscopy (EIS) electrical impedance ranging from about 200 ohms to about 250 ohms at a frequency ranging from about 7 Hz to about 20 Hz.

11. The electrode of claim 1 wherein the substrate is selected from a material consisting of iridium, platinum, palladium, platinum iridium alloys, palladium iridium alloys, titanium, titanium tungsten, gold alloys, conductive polymers, and combinations thereof.

12. The electrode of claim 1 wherein the substrate surface is an external surface of a helically shaped electrode, a dome shaped electrode, a Utah electrode array, or a Michigan electrode array.

13. A method of applying an iridium oxide layer, the method comprising:
a) providing a substrate having a surface adaptable to interface with biological tissue;
b) positioning the substrate within a sputter chamber of a sputter instrument;
c) evacuating the sputter chamber;
d) injecting a mixture of gases into the sputter chamber; and
e) energizing the sputter instrument such that a layer of iridium oxide is deposited on the surface of the substrate by a pulse DC sputtering technique.

14. The method of claim 13 including providing a sputter pressure within the sputter chamber ranging from about 25 mTorr to about 50 mTorr.

15. The method of claim 13 including providing a pulse sputter power ranging from about 25 Watts to about 150 Watts.

16. The method of claim 13 including providing a reverse bias having a time duration ranging from about 1 μsec to about 10 μsec.

17. The method of claim 13 including exposing the surface of the substrate to the mixture of gases having a reactive gas mixing ratio defined by the equation: (flow rate of gas “A”)/(flow rate of gas “A”+flow rate of gas “B”), wherein gas “A” or gas “B” comprises oxygen, argon, nitrogen, helium, neon, and combinations thereof, and wherein gases “A” and “B” are different.

18. The method of claim 17 including providing the reactive gas mixing ratio from about 1 percent to about 50 percent.

19. The method of claim 17 including providing the reactive gas mixing ratio from about 1 percent to about 5 percent.

20. The method of claim 17 including providing a duty cycle percentage ranging from about 15 percent to about 25 percent.

21. The method of claim 13 including providing the layer of iridium oxide comprising a fractal cauliflower-like morphology and an amorphous structure.

22. The method of claim 13 including selecting the substrate from a material consisting of iridium, platinum, palladium, platinum iridium alloys, palladium iridium alloys, titanium, titanium tungsten, gold alloys, conductive polymers, and combinations thereof.

23. The method of claim 13 including providing the substrate surface of an external surface of a helically shaped electrode, a dome shaped electrode, a Utah electrode array, or a Michigan electrode array.
